(19) United States
(12) Patent Application Publication
(10) Pub. No.: US 2024/0175133 A1
(43) Pub. Date: May 30, 2024

(54) MULTI-DISC CHEMICAL VAPOR DEPOSITION SYSTEM WITH CROSS FLOW GAS INJECTION

(71) Applicant: VEECO INSTRUMENTS INC., Plainview, NY (US)

(72) Inventors: Ajit Paranjpe, Plainview, NY (US); Johannes Kaeppeler, Lontzen (BE); Alexander Gurary, Plainview, NY (US)

(73) Assignee: VEECO INSTRUMENTS INC., Plainview, NY (US)

(21) Appl. No.: 18/519,548

(22) Filed: Nov. 27, 2023

Related U.S. Application Data
(60) Provisional application No. 63/428,250, filed on Nov. 28, 2022.
(60) Provisional application No. 63/428,261, filed on Nov. 28, 2022.

(51) Int. Cl. C23C 16/458; C23C 16/455; C30B 25/10; C30B 25/12; C30B 25/14

(52) U.S. Cl. CPC C23C 16/4584; C23C 16/45502; C23C 16/45565; C23C 16/4586; C30B 25/10; C30B 25/12; C30B 25/14

(57) ABSTRACT

A multi-wafer metal organic chemical vapor deposition system in which adjacent wafers positioned within the system rotate about their own axes, including a reaction chamber comprising an exhaust system including a peripheral port, a multi-wafer carrier comprising a wafer carrier body and a plurality of wafer carrier discs supported within the wafer carrier body, wherein adjacent wafer carrier discs of the plurality wafer carrier discs are configured and the wafer carrier body are configured to rotate at different speeds, a multi-zone injection block positioned over the wafer carrier body, a central gas port positioned in the center of the wafer carrier body that can be configured as a gas exhaust or a gas injection port, and a multi-zone heater assembly positioned beneath the multi-wafer carrier.

### CROSS-REFERENCE TO RELATED APPLICATION

The present application claims the benefit of and priority to U.S. patent application Ser. No. 63/428,250, filed Nov. 28, 2022, and U.S. patent application Ser. No. 63/428,261, filed Nov. 28, 2022, each of which is hereby incorporated by reference in its entirety.

### TECHNICAL FIELD

The present technology is generally related to semiconductor fabrication technology and, more particularly to chemical vapor deposition processing and associated systems having the high-performance standards of a single wafer reactor, with the productivity metrics of a high-capacity, multi-wafer batch reactor. More particularly, the present disclosure recites and illustrates chemical vapor deposition processing and associated system that are configured to avoid or significantly minimize parasitic deposition on the ceiling. This can eliminate or reduce the need for in-situ cleaning, enhance component lifetimes, increase growth rates, increase gas usage efficiency, and broaden the process window for deposition uniformity on the wafer. Elimination or reduction of in-situ cleaning shortens the cycle time and extends the preventative maintenance cycle.

### BACKGROUND

Certain processes for fabrication of semiconductors can require a complex process for growing epitaxial layers to create multilayer semiconductor structures for use in fabrication of high-performance devices, such as light emitting diodes (LEDs), laser diodes, optical detectors, power electronics, and field effect transistors. In this process, the epitaxial layers are grown through a general process called chemical vapor deposition (CVD). One type of CVD process is called metal organic chemical vapor deposition (MOCVD). In MOCVD, reactant gases are introduced into a reactor chamber within a controlled environment that enables the reactor gas to react on a substrate (commonly referred to as a “wafer”) to grow thin epitaxial layers.

During epitaxial layer growth, several process parameters are controlled, such as temperature, pressure, and gas flow rate, to achieve desired quality in the epitaxial layers. Different layers are grown using different materials and process parameters. For example, devices formed from compound semiconductors such as III-V or IV-IV semiconductors, typically are formed by growing a series of distinct layers. In this process, the wafers are exposed to a combination of reactant gases, typically including a metal organic compound such as an alkyl source that includes a group III metal, such as aluminum (Al), gallium (Ga), indium (In), and combinations thereof, and a hydride source that includes a Group V element, such as nitrogen (N), phosphorus (P), arsenic (As), or antimony (Sb), typically in the form of NH₃, AsH₃, PH₃, or an Sb metalorganic, such as tetramethyl antimony. In the case of IV-IV at least two elements of Silicon (Si) and Carbon (C) and Germanium (Ge) are formed by typically used as hydrides for example SiH₄, Si₂H₆ C₂H₄, C₃H₈, GeH₄ or chloride based gases by SiH₂Cl₂, SiHCl₃, Generally, the alkyl and hydride sources are combined with a carrier gas, such as nitrogen (N₂), Argon (Ar) and hydrogen (H₂), or a mixture of a combination of H₂ with N₂ or Ar which do not participate appreciably in the reaction. In these processes, the alkyl and hydride sources flow over the surface of the wafer and react with one another to form a III-V compound of the general formula In_{X}Ga_{Y}Al_{Z}N_{A}As_{B}P_{C}Sb_{D}, where X+Y+Z equals approximately one. A+B+C+D equals approximately one, and each of X, Y, Z, A, B, C, and D can be between zero and one. In other processes, commonly referred to as “halide” or “chloride” processes, the Group III metal source is a volatile halide of the metal or metals, most commonly a chloride such as GaCl₂. In yet other processes, bismuth is used in place of some or all the other Group III metals.

A suitable substrate for the reaction can be in the form of a wafer having metallic, semiconducting, and/or insulating properties. In some processes the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a rotating disk reactor architecture-based CVD process chamber, one or more wafers are positioned within a rapidly rotating carousel, commonly referred to as a “wafer carrier,” so that the top surface of each wafer is exposed, thereby providing a uniform exposure of the top surface of the wafer to the atmosphere within the reactor chamber for the deposition of semiconductor materials. The wafer carriers are typically machined out of a highly thermally conductive material such as graphite and are often coated with a protective layer of a material such as silicon carbide or tantalum carbide. Each wafer carrier has a set of circular indentations, or pockets, in its top surface in which individual wafers are placed. The wafer carrier is commonly rotated at a rotation speed on the order from about 50 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between about 550-1200° C. for GaN based films. Higher temperatures (e.g., up to about 1450° C.) are used for growth of AlN based films and lower temperatures (e.g., down to about 350ºC) are used for growth of AsP films. For some materials such as SiC, temperatures of 1600° C.-1700° C. are required. Other temperature ranges are suitable for other materials such as SiC, Si and SiGe or 2D materials such as graphene, and sulphides or selenides of tungsten and molybdenum. The reactive gases, however, are introduced into the chamber by the gas distribution device at a much lower temperature, typically about 200° ° C., or lower, to inhibit premature reaction of the gases.

As the reactant gases approach the rotating wafer carrier, the temperature of the reactant gases substantially increases and viscous drag of the rotating wafer carrier impels the gases into rotation about an axis of the wafer carrier, so that the gases flow around the axis and outwardly toward a perimeter of the wafer carrier across the boundary region near the surface of the wafer carrier. Depending on the reactant gases used in the process, pyrolysis can occur in or near the boundary region at an intermediate temperature between that of the gas distribution device and the wafer carrier. This pyrolysis creates intermediate species that facilitate growth of a crystalline structure. The gases that are not consumed continue to flow toward the perimeter and over the outer edge of the carrier, where they are removed from the process chamber through one or more exhaust ports disposed below the wafer carrier.

Presently, two broad categories of process chambers exist today that are based on the rotating disk reactor concept: (1) high-performance single wafer reactors, such as the PROPEL™ GaN MOCVD system, manufactured by Vecco Instruments Inc. of Plainview, NY, capable of depositing high-quality GaN films on 200 mm (8 inch) and 300 mm (12 inch) silicon wafers for applications such as power, RF and photonics; and (2) high-capacity multi-wafer reactors, such as the TurboDisc EPIK® family of MOCVD systems, also manufactured by Veeco Instruments Inc. of Plainview, NY, designed for mass production of mini- and micro-LEDs, typically on 100 mm (4 inch) or 150 mm (6 inch) silicon wafers, and a related family of products referred to as K475i and Lumina for growth of AsP based films. Although such systems have proven to work exceptionally well, there is a continuing desire to produce even higher efficiency process chambers, which have a higher capex efficiency (ratio of throughput to capital investment), smaller footprints and lower associated operating costs, while maintaining the high-quality deposition standards required, for example, of certain GaN film applications.

In particular, several emerging applications (e.g., micro-LEDs) place very stringent requirements on the uniformity of the wavelength and film thickness while also requiring very low defectivity levels to be achieved. For blue micro-LEDs for example, the range of acceptable wavelengths is 2 nm, the range of thickness variation is 4%, and the allowable defectivity levels for defects larger than 1 μm is 0.1/cm². In order to achieve these stringent requirements, uniformity must be achieved simultaneously for several parameters over the substrate. This includes the gas flow rate, boundary layer thickness, gas temperature, and wafer temperature. Since the substrate bows appreciably during the growth and its bow differs during various stages of growth, dynamic temperature control of the pocket under the wafer is necessary to ensure that a uniform wafer temperature is maintained during all stages of growth. A single wafer reactor in which the substrate is spinning about its axis and the gas flow towards the substrate encounters the wafer before flowing over the carrier provides these attributes, while to date these same attributes have been impossible to consistently achieve in a conventional multi-disc batch reactor. The present disclosure addresses this concern as well as others.

### SUMMARY OF THE DISCLOSURE

The techniques of this disclosure generally relate to chemical vapor deposition processing systems and associated methods having the high-performance deposition standards of a single wafer reactor, with the productivity metrics of a high-capacity, multi-wafer batch reactor. In embodiments, the present disclosure includes reactors capable of processing multiple rotating disks, with each disk emulating a single wafer reactor integrated into a batch reactor, so that a common gas delivery system, injector, heater assembly, in-situ metrology, chamber body, exhaust, and rotation mechanism can be shared between the discs. To achieve a high degree of consistency in epitaxial growth, in some embodiments, for example, the discs can be rotated in a circular, oval, racetrack or any other closed path within the chamber, such that each of the discs experience a nearly identical time averaged process environment. Accordingly, embodiments of the present disclosure describe higher capex efficiency, more compact (e.g., smaller footprint) chemical vapor deposition systems with lower operating costs, without compromising deposition quality.

One embodiment of the present disclosure provides a multi-wafer metal organic chemical vapor deposition system in which adjacent wafers positioned within the system rotate about their own axes, including a reaction chamber having an exhaust system, a multi-wafer carrier including a wafer carrier body and a plurality of wafer carrier discs supported within the wafer carrier body, an injection block having at least one injection zone positioned over the multi-wafer carrier, a center gas injection port positioned in a center of the multi-wafer carrier, and a heater assembly positioned beneath the multi-wafer carrier.

In one embodiment, a multi-wafer metal organic chemical vapor deposition system is disclosed in which adjacent wafers positioned within the system rotate about their own axes. A gas injector is provided for injecting gas into the reaction chamber. The system has a movable cover plate that is configured to act as a barrier to deposition gases for minimizing growth rate non-uniformity induced around edges of the wafer. The movable cover plate moves between a lowered home position that allows for loading and unloading of the wafer carrier body and a raised operating position that comprises an active deposition position.

The system can include a lift mechanism for moving the cover plate between the lowered home position and the raised operating position and the lift mechanism is configured to permit rotation of the multi-wafer carrier. The lift mechanism can, in one embodiment, include a plurality of lift pins that pass through corresponding through holes in the multi-wafer carrier and are configured to drive the cover plate from the lowered home position to the raised operating position and permit lowering of the cover plate. The lift mechanism is rotatable to accommodate rotation of the wafer carrier. In addition, the lift mechanism includes a motor that is configured to controllably rotate the cover plate between a plurality of indexed positions. Alternatively, the cover plate can be moved up/down by movement of the center gas injector if a movable center gas injector is used.

In another embodiment, the gas injector comprises a center gas injector that is movable between a raised operating position and a lowered home position and movement of the center gas injector between the lowered home position and the raised operating position is translated into movement of the cover plate between the lowered home position and the raised operating position.

In addition, a water-cooled plate can be disposed above the cover plate for thermal regulation of the cover plate.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is a cross-sectional view of a precision, multi-wafer metal organic chemical vapor deposition system with cross flow gas injection.

FIG. 2 is a cross-sectional view of one portion of the system of FIG. 1.

FIG. 3 is another cross-sectional view of another portion of the system of FIG. 1.

FIG. 4 is a cross-sectional view of the system of FIG. 1 with a movable center gas injector being shown in the raised position.

FIG. 5 is a top view of a split coil assembly for the susceptor of the system of FIG. 1.

FIG. 6 is a top view of the susceptor and its position for satellites and susceptor pins.

FIG. 7 is a top view of a ceiling coil of the system of FIG. 1.

FIG. 8 is a cross-sectional view of a gas driven rotation drive.

FIG. 9 is a cross-sectional view of a multi-wafer metal organic chemical vapor deposition system with cross flow gas injection and a multiple zone resistance heating arrangement for a GaN application.

FIG. 10 is a cross-sectional view of an automated wafer loading and unloading mechanism in accordance with one embodiment showing the center gas injector in the raised (in process) position.

FIG. 11 is a cross-sectional view of the mechanism of FIG. 10 in the loading and unloading position with the center gas injector in the lowered position.

FIG. 12 is a cross-sectional view of a loading and unloading mechanism utilizing a Bernoulli gripper.

FIG. 13 is a cross-sectional view of an automated wafer loading and unloading mechanism in accordance with one embodiment and including lift pins that are shown in the lowered position.

FIG. 14 is a cross-sectional view of the mechanism of FIG. 13 with the lift pins in the raised position.

FIG. 15 is a cross-sectional view of an automated wafer loading and unloading mechanism in accordance with another embodiment showing the center gas injector in the raised (in process) position.

FIG. 16 is a cross-sectional view of the mechanism of FIG. 15 with the center gas injector in the lowered position.

FIG. 17 is a cross-sectional view of an automated wafer loading and unloading mechanism in accordance with one embodiment and including lift pins that are shown in the lowered position.

FIG. 18 is a cross-sectional view of the mechanism of FIG. 17 with the lift pins in the raised position.

FIG. 19 is a top plan view of a separated wafer carrier.

FIG. 20 is a cross-sectional view showing one section of the separated wafer carrier in a raised position.

FIG. 21 is a cross-sectional view of a rotatable platform and satellite ring that is driven by a common motor through separate gears to achieve a differential in rotational speed between rotatable platform and satellite ring.

FIG. 22 is an enlarged cross-sectional view of the satellite of FIG. 21 that consists of a disc with a hub at the bottom.

FIG. 23 is a cross-sectional, schematic view depicting a centrally located multi-zone injector including at least two distinct zones for the distribution of reactant gases into a reaction chamber in a crossflow direction, in accordance with an embodiment of the disclosure.

FIG. 24A is a cross-sectional, schematic view depicting a multi-wafer metal organic chemical vapor deposition system including a centrally located injector configured to selectively lift a movable cover plate, wherein the cover plate is in the home position, in accordance with an embodiment of the disclosure

FIG. 24B depicts the multi-wafer metal organic chemical vapor deposition system of FIG. 24A, wherein the cover plate is in the active position, in accordance with an embodiment of the disclosure.

FIG. 25 is a partial cross-sectional view depicting a mechanism for cooling or thermal regulation of the cover plate.

FIG. 26 is a partial, cross-sectional view depicting a substrate wafer residing within a pocket defined in an individual wafer supporting disc of a wafer carrier, in accordance with an embodiment of the disclosure.

FIG. 27 is a cross-sectional view of a precision, multi-wafer metal organic chemical vapor deposition system with cross flow gas injection according to another embodiment.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION

As wafer sizes for III-V epitaxial growth have increased from 150 mm diameter wafers to larger diameter wafers, such as 200 mm and 300 mm diameter wafers, consumer preference has generally tended towards single wafer reactors, such as the PROPEL™ GaN MOCVD system, due to its superior uniformity and process control. An example embodiment of the PROPEL™ GaN MOCVD system is disclosed in US Pat. App. Publ. No. 2017/0067163, the contents of which are incorporated by reference herein. Advantages for single wafer reactors include rotational averaging for improved deposition uniformity without leading and/or trailing edge effects, low centripetal forces on the wafer, and a wide process window (e.g., 25 Torr, 1450° C., 3000 RPM, etc.). Single wafer reactors are also more readily adaptable to hot wire chemical vapor deposition (alternatively referred to as “catalytic chemical vapor deposition”), a deposition method in which the precursor gas is catalytically disassociated at resistive heating filaments.

However, single wafer reactors are generally considered less cost-effective than multi-wafer batch reactors especially for 150 mm and 200 mm wafers in certain applications. In particular, batch reactors, such as the TurboDisc EPIK® family of MOCVD systems typically have a higher footprint efficiency, higher capital expenditure efficiency, and overall lower cost of ownership. Examples of the TurboDisc EPIK® family of MOCVD systems are disclosed in US Pat. App. Publ. Nos. 2007/0186853 and 2012/0040097, and U.S. Pat. Nos. 6,492,625; 6,506,252; 6,902,623; 8,021,487; and 8,092,599, the contents of which are incorporated by reference herein. With 300 mm diameter wafers, the differential in the metrics between single wafer reactors and batch reactors is relatively small, with single wafer reactors being the preferred choice. However, with wafers having a diameter of less than 300 mm (e.g., 200 mm and 150 mm diameter wafers), higher capacity batch reactors are the preferred choice. Unfortunately, to date, batch reactors have not been able to meet the precision deposition requirements of every application.

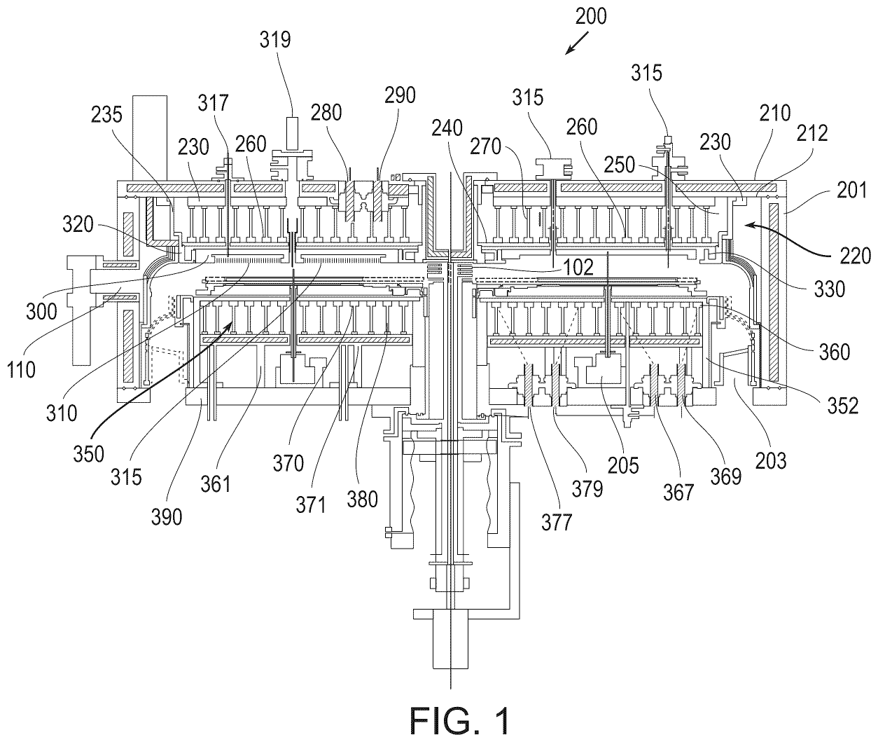

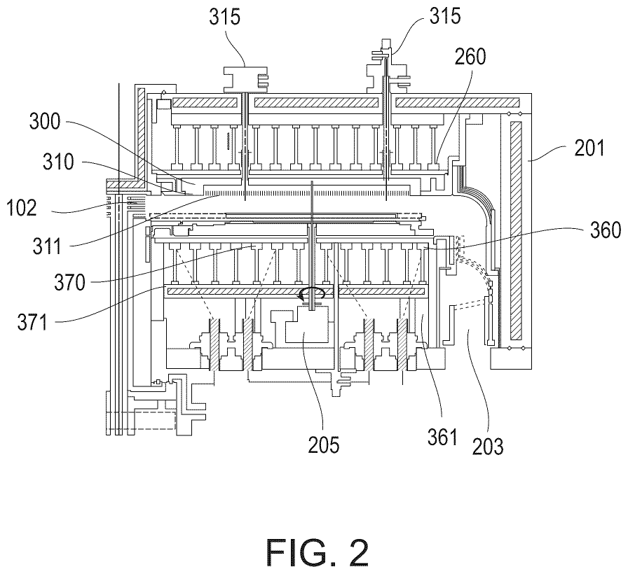

Referring to FIGS. 1-2, a precision, multi-wafer metal organic chemical vapor deposition system 200 configured to achieve the performance of a single wafer reactor, with the productivity and efficiency of a multi-disc batch reactor, is depicted in accordance with an embodiment of the disclosure. In embodiments, the precision, multi-wafer metal organic chemical vapor deposition system 200 can include a reaction chamber 201 (occasionally referred to herein as a “process chamber” or “reactor”), configured to define a process environment space, in which an injector 102 (alternatively referred to herein as a “gas distribution device”) can be arranged within the environment space.

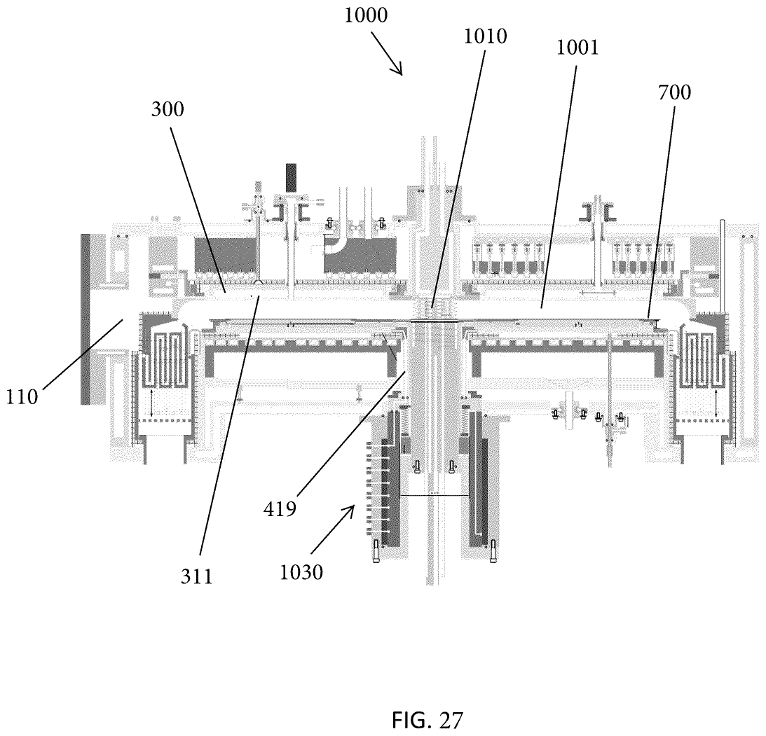

The end of the reaction chamber 201 in which the injector 102 of FIGS. 1 and 2 is placed can be referred to as the “top” end of the reaction chamber 201. This end of the chamber typically, but not necessarily, is disposed at the top of the chamber in the normal gravitational frame of reference. Thus, the downward direction as used herein refers to the direction away from the injector 102; whereas the upward direction refers to the direction within the chamber, toward the injector 102, regardless of whether the directions are aligned with the gravitational upward and downward directions. Similarly, the “top” and “bottom” surfaces of elements may be described herein with reference to the frame of reference of the reaction chamber 201 and the injector 102. The construction of an inverted system 200, in which the process gases flow upwardly from a bottom of the reaction chamber 201 is also contemplated. The injector 102 can be centrally positioned within the process chamber (such as that depicted in FIGS. 1 and 27) to affect a substantially horizontal or crossflow of reactant gases over substrates positioned within the reaction chamber 201.

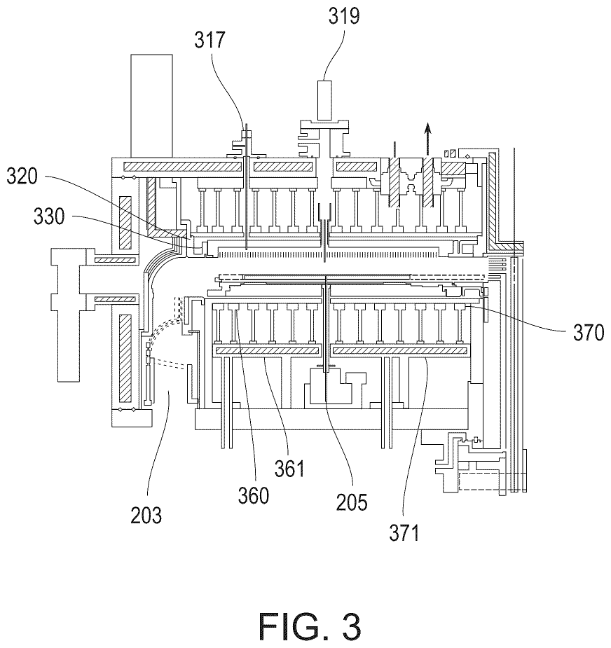

FIGS. 1-7 disclose a precision, multi-wafer metal organic chemical vapor deposition system 200 according to one embodiment. The system 200 includes a reaction chamber 201. The system 200 can be thought of as including an upper (ceiling or lid) region and a lower (substrate) region. The upper region includes the ceiling of the reaction chamber 201, while the lower region contains the wafer carrier.

Along the sidewall of the system, there is also a load port 110 for loading and unloading the wafer carrier. The loading and unloading of the wafer carrier are discussed in more detail below.

The reaction chamber 201 comprises a hot wall reactor and includes a heated sidewall that is water-cooled as a result of the sidewall having an internal chamber in which water is circulated. This mechanism allows for controlled sidewall temperature of the reaction chamber 201.

### Heated and Purged Ceiling

In the system 200, the ceiling of the reaction chamber 201 is both heated and includes a showerhead architecture for injecting purge gases into the reaction chamber 201.

At the top of the reaction chamber 201 is a lid that is defined by a top wall 210 with water-cooling for temperature control. The top wall 210 also includes through ports that pass completely through the top wall 210 and other openings for receiving related equipment as described herein. The top wall 210 can thus include an internal chamber (annular space) in which water is circulated. The top wall 210 includes an inner surface or face 212. The lid is thus water-cooled.

A ceiling heater assembly 220 is provided and is positioned between the top wall 210 and the hollow interior of the reaction chamber 201 that contains the wafer carrier and is disposed along the inner face 212 of the top wall 210. The ceiling heater assembly 220 can include one or more support brackets 230 that are coupled to the inner face 212. Much like the top wall 210, the support brackets 230 include through ports that align with those formed through the top wall 210. The one or more support brackets 230 can be formed of quartz or other suitable material. One or more support clamps 235 are provided and coupled to the one or more support brackets 230.

The ceiling heater assembly 220 includes a diffusion barrier 240 that is spaced from top wall 210 and is disposed parallel to the top wall 210. The diffusion barrier 240 is formed of a suitable material (e.g., quartz) that can withstand the operating temperatures of the reaction chamber 201. The diffusion barrier 240 prevents diffusion of the gases from the reaction chamber 201 into the ceiling and the ceiling heater assembly 220.

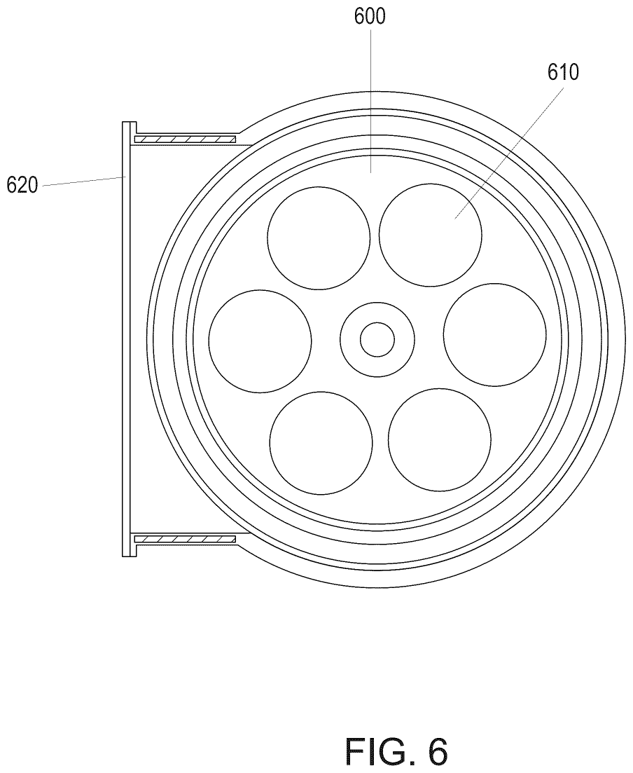

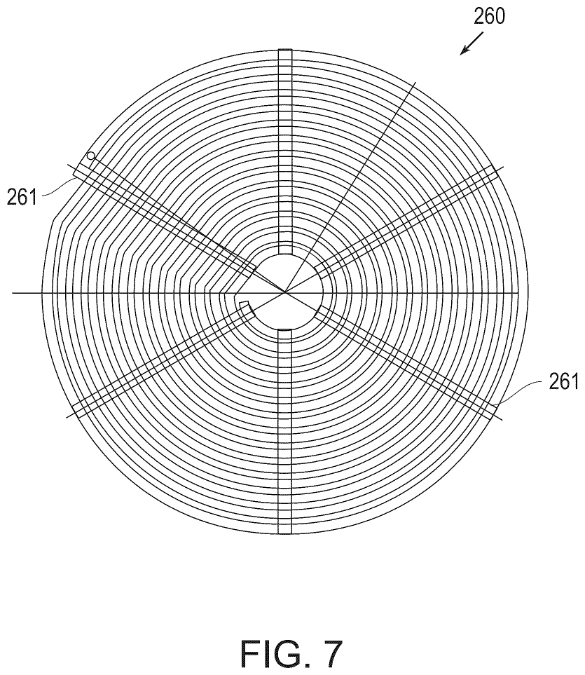

Between the diffusion barrier 240 and the support bracket 230 there is a heater cavity 250 that comprises an open space in which the active components of the ceiling heater are located. The main active component of the ceiling heater comprises a ceiling heater coil 260 and more particularly, the ceiling heater coil 260 can be an RF coil that is water-cooled. The RF coil can be formed of copper and has a hollow center though which the cooling water flows. FIG. 7 illustrates one exemplary RF ceiling heater coil 260 that has a concentric, circular shape. Stabilizing bars 261 are shown in FIG. 7 for stabilizing the coil itself. As shown in FIG. 1, (quartz) coil supports/pedestals 270 are provided for mounting the ceiling heater coil 260 to the one or more support brackets 230 and for suspending the RF ceiling heater coil 260.

As part of the cooling circuit, there are one or more water inlets 280 that provide water to the RF ceiling heater coil 260 and one or more water outlets 290 that withdraw water from the RF ceiling heater coil 260. The water inlet(s) 280 and water outlet(s) 290 are in fluid communication with the hollow interior of the ceiling heater coil 260 through which the water flows.

The ceiling heater assembly 220 is intended to heat the ceiling of the system 200. More particularly, in the exemplary embodiment discussed herein, the ceiling heater assembly 220 operates at higher temperatures than the temperatures of the heater (discussed herein) that heats the susceptor.

The ceiling of the system 200 is formed of a top ceiling plate 300 and a lower ceiling plate 310 that is spaced from the top ceiling plate 300. The top ceiling plate 300 is disposed adjacent the diffusion barrier 240 and there is an open space 315 formed between the top ceiling plate 300 and the lower ceiling plate 310. This open space 315 can be thought of as being a gas manifold that distributes gas and permits gas to being injected into the reaction chamber 201. The open space 315 thus has an annular shape.

The top ceiling plate 300 is configured and intended to absorb energy from the RF heater (RF ceiling heater coil 260).

The top ceiling plate 300 includes ports (openings) that align with at least some of the ports through the diffusion barrier 240 to permit passage of equipment such as temperature measuring equipment and gas injector devices/nozzles. The lower ceiling plate 310 includes a plurality of showerhead holes 311 (FIG. 2) that communicate directly into the reaction chamber 201. Gases that are injected into the open space 315 flow throughout the open space 315 and exit through the showerhead holes 311. The showerhead holes 311 can be formed in different patterns to allow the uniform distribution of the gases into the reaction chamber 201.

As described herein, the showerhead design permits ceiling purging and more particularly, the showerhead in the ceiling permits injection of carrier gas (H2, N2, Ar or a combination thereof) and for some applications, injection of an etching gas (e.g., HCl, Cl2, TBCl, etc.).

The ceiling of the system 200 is mounted to the lid using suitable mounting structures. For example, an outer support ring 320 and an outer intermediate ring 330 can be used to mount the ceiling heater assembly to the lid. The outer intermediate ring 330 is located radially inward from the outer support ring 320. Rings 320, 330 can be formed of quartz.

The ceiling of the system 200 is actively heated with a heat source separate from the susceptor heating system. In accordance with one aspect of the present system 200, the operating temperature of the ceiling heater assembly 220 is different than bottom (susceptor) heater assembly that heats the wafer carrier. Therefore, the temperature gradient between the ceiling and the susceptor holding the substrate can be reduced to suppress the convection by temperature gradient towards the ceiling.

For example, the operating temperature of the ceiling heater assembly 220 is higher than the operating temperature of the bottom (susceptor) heater assembly. For example, the operating temperature of the ceiling heater assembly 220 can be between 600° C. and 1200° C. or 700° C. and 1100° C., or 1600° C. and 1800° C. and, while the operating temperature of the bottom heater assembly is between 600° C. to 900° ° C. or 700° C. and 1400° C., or 1500° C. and 1700° C.

The gas purging results from the introduction of gases into the reaction chamber 201 through the ceiling (showerhead holes 311). In one embodiment, one or more showerhead gas modules 315 can be provided along the lid and pass through the ports formed through the top wall and diffusion barrier and passes through a port formed in the top ceiling plate 300. In this way, one or more gases, such as a carrier gas, such as H2/Ar, and/or an etching gas, such as HCl, are directly injected into the open space 315 and then exit through the showerhead holes 311 into the reaction chamber 201 according to a desired, predefined pattern.

Additional, measurement equipment, is included and disposed along the lid. For example, a ceiling pyrometer 317 with lightpipe can be provided and used to monitor the temperature of the ceiling. The ceiling pyrometer 317 passes through the top wall and the diffusion barrier and a distal end of the ceiling pyrometer 317 is disposed with an open space between the top ceiling plate 300 and the diffusion barrier. In addition, a pyrometer and view port 319 can be provided to obtain measurements and direct view of the wafer (substrate).

### SiC Application

In the case of SiC epitaxy, the ceiling temperature is heated between 1600° C. and 1800° C. due to heating by the RF pancake coil (RF ceiling heater coil 260). The temperature of the contact to the quartz should not exceed 1200° ° C. Therefore, at least two intermediate rings 330 are in between the ceiling and the quartz support to lower the temperature and additionally reduce the thermal stress. The material selection for the ceiling and the susceptor is more restrictive in SiC applications because of the high temperature and the interaction with the carrier and process gases. In the case of SiC epitaxy, there will be only graphite with TaC coating or SiC coating or solid SiC. The limit of SiC coating is removal of the coating via sublimination if it comes into proximity with a colder surface.

### GaN Application

For a GaN application, the ceiling temperature is heated between 700° ° C. and 1100° C. due to heating by the RF pancake coil (RF ceiling heater coil 260). The material selection for the ceiling and the susceptor is less restrictive but nevertheless it should be protected from hot ammonia which requires a protective coating of the graphite. The preferred coating is SiC, but TaC or pyrolytic boron nitride can alternatively be used as a coating. Also, solid SiC can be used for some parts such as cover plates, satellites, satellite rings, etc.

The susceptor can also be heated to 700° C. and 1400° C. by restrictive heating using filaments that are preferably made of W or Re. Resistive heating provides multiple zone temperature control which is not possible with RF heating.

### GaAs/InP Application

For GaAs/InP application, the temperature of the ceiling can be between 600° C. and 1200° ° C. using RF with the pancake coil (RF ceiling heater coil 260). The material selection for the ceiling and the susceptor is less restrictive and preferably is highly purified graphite.

### GaN

As for GaN, resistive heating up to 600° ° C. to 900° C. using filaments that are preferably made of pure graphite can be used.

In all cases, ceiling temperatures higher or lower than those mentioned above can be used since the optimal temperatures are dependent on the process chemistry and the operating conditions.

### Susceptor Heating Assembly

A susceptor heating assembly 350 is provided for heating the wafer carrier.

The susceptor heating assembly 350 includes a liner 352 that is below the susceptor but above the active components of the susceptor heating assembly 350. The liner 352 can be formed of quartz.

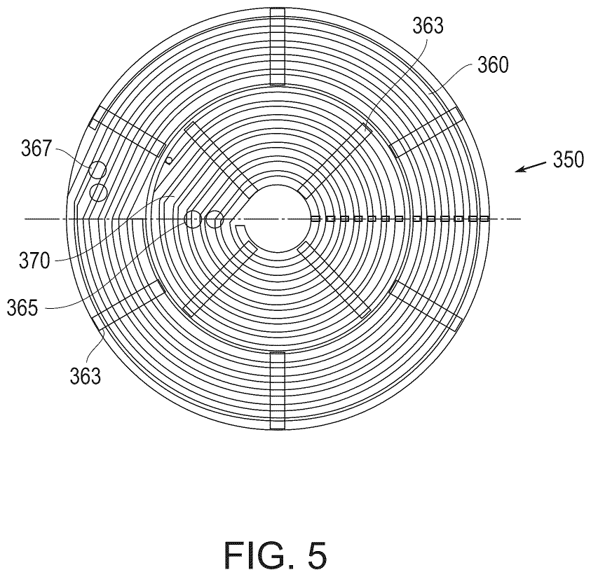

The susceptor heating assembly 350, as shown in FIG. 5, has a different construction than the ceiling heater assembly 220. More particularly, the susceptor heating assembly 350 has an outer susceptor heater coil 360 and an inner susceptor heater coil 370 that is coupled to the outer susceptor heater coil 360. The outer susceptor heater coil 360 is located radially outward from the inner susceptor heater coil 370.

The outer susceptor heater coil 360 includes a water inlet 368 (FIG. 1) for delivering water into the coil 360 and a water outlet 369 (FIG. 1) for withdrawing water from the coil 360. Similarly, the inner susceptor heater coil 370 includes a water inlet 377 for delivering water into the coil 370 and a water outlet 379 for withdrawing water from the coil 370 (FIG. 1).

Each of the outer susceptor heater coil 360 and the inner susceptor heater coil 370 is similar to the RF ceiling heater coil 260 and is in the form of a water-cooled RF coil. The RF coil can be formed of copper with internal water cooling. The coils 360, 370 are located directly below the liner 352.

Despite the susceptor heater assembly being of a split coil design in this embodiment, the combined coils 360, 370 function as a single coil. FIG. 5 shows the split coil design with feedthroughs as well as stabilizing bars 363 similar to the ceiling coil. One feedthrough 365 serves to connect the inner and outer heater coils 360, 370, while another feedthrough 367 connects the split heater coil to an external RF source. Other openings (through holes) are for passage of external devices, such as lightpipes, etc. The circle shown in FIG. 5 to the right of feedthrough 365 is another coil feedthrough similar or identical to feedthrough 365. The circle shown in FIG. 5 below the feedthrough 367 is another coil feed connection similar to or identical to feedthrough 367.

Each of the outer susceptor heater coil 360 and the inner susceptor heater coil 370 is supported by a support structure. More particularly, the outer susceptor heater coil 360 is supported by an outer coil support plate 361 that has water cooling and similarly, the inner susceptor heating coil 370 is supported by an inner coil support plate 371 (FIG. 1). The outer coil support plate 361 is located radially outward from the inner coil support plate 371 and each of these parts is hollow to receive and permit circulation of the water. There is a water inlet for delivering water into the coil support plates 361, 371 and a water outlet for withdrawing water from the coil support plates 361, 371. In addition, coil pedestals/supports 380, made of quartz, support the coils 360, 370 on the respective coil support plates 361, 371.

A bottom plate 390 is provided and acts as a support for the outer coil support plate 361 and the inner coil support plate 371. The bottom plate 390 includes the feedthroughs (ports/openings) for the susceptor heater assembly, with feedthroughs to water-cooled coil support plates 361, 371, the feedthrough for mechanical main rotation and satellite rotation or satellite gas drive rotation as described herein. The bottom plate 390 further includes a vacuum connection to the shutter including the exhaust collector and the gas injector 102 which introduces up to 3, 5, or 7 different concentric horizontal gas inlet zones. As mentioned previously, the gas injector 102 can be lowered to a position (the lowered position) which clears the access to unload and load the complete wafer carrier from and to the transport chamber by a robot in one embodiment.

As also further described herein, the bottom plate 390 supports the mechanical equipment, such as gear boxes, that is configured to rotate both the wafer carrier and the satellites.

In at least one embodiment, resistive heating can be used for susceptor in order to provide temperature tunability.

Gas Injection into the Reaction Chamber

As mentioned herein, gases are injected into the reaction chamber 201 in at least two different locations and by at least two different means.

First, the ceiling showerhead 310, 311 permits injection of one or more carrier gases and/or one or more etching gases. The showerhead design allows for these gases to be injected through the heated ceiling into the reaction chamber 201 in a controlled manner. Second, the center injector 102 acts to inject the reactant gases along the plurality of horizontal concentric zones defined within the center gas injector 102. The reactant gases flow radially outward from the center of the reaction chamber 201 over the substrates on the satellites.

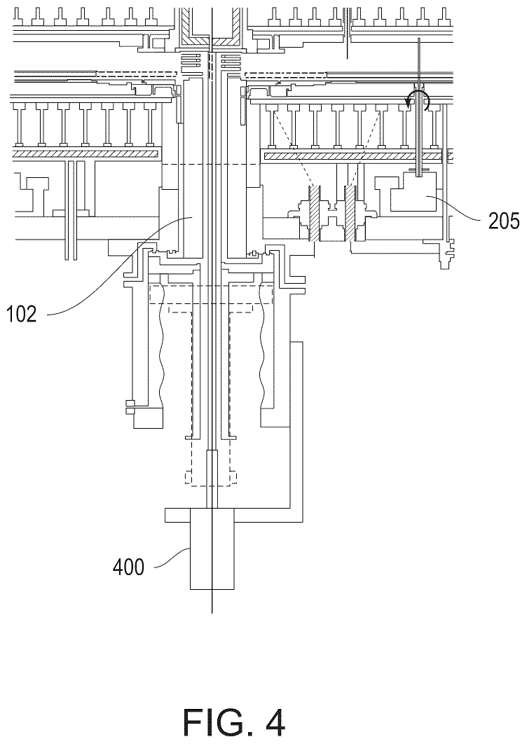

Additional details concerning the cross-flow gas injector 102 that is illustrated in FIG. 1 are as follows and are shown in the enlarged view of FIG. 4. The cross-flow gas injector 102 moves between the raised and lowered positions using a conventional drive mechanism, such as a pneumatic drive mechanism. For example, a pneumatic piston 400 can controllably drive the main body of the cross-flow gas injector 102 that includes the plurality of concentrically arranged horizontal gas inlets. The body of the cross-flow gas injector 102 includes plumbing that routes the reactant (process) gases through the body to the plurality of horizontal gas inlets. In addition, the body of the cross-flow gas injector 102 can be water-cooled. In addition, vacuum connections can be provided as part of the cross-flow gas injector 102.

In the lowered position of the cross-flow gas injector 102, the reactant (process) gas is in the off position since none of the gas injector zones are open and located above the wafer.

### Parasitic Deposition on the Ceiling

As mentioned, one of the primary disadvantages of conventional planetary reactor systems is the parasitic deposition on the ceiling. Parasitic deposition can cause particle generation and alter the thermal balance within the reactor which leads to process drift. To avoid this, in-situ chamber etching is often used but this will increase the total cycle time for a production run. In-situ cleaning typically reduces component lifetimes and therefore increases the costs of consumables. In-situ etching is impractical for certain materials, such as SiC, that are difficult to etch in typical in-situ cleaning gases, such as Cl2, HCl and NF3.

Additionally, the parasitic deposition consumes precursor materials which will not end up in the active layer on the substrate. This reduces the total precursor usage efficiency and limits the process window for good uniformity (e.g., for thickness, composition and doping) on the wafer.

The system 200 disclosed herein is configured to avoid or significantly minimize the parasitic deposition on the ceiling. This can eliminate or reduce the need for in-situ cleaning, enhance component lifetimes, increase growth rates, increase gas usage efficiency, and broaden the process window for deposition uniformity on the wafer. Elimination or reduction of in-situ cleaning shortens the cycle time and extends the preventative maintenance cycle.

The system 200 uses a combination of flows introduced by vertical (showerhead design 310, 311) and horizontal (injector 102) gas inlets in conjunction with carrier rotation speeds that are 2× to 20× higher than carrier rotation speeds in a typical cross flow planetary reactor to achieve efficient layer growth on the substrate. The present cross flow reactor (system 200) thus combines a cross flow planetary arrangement with higher speed carrier rotation.

Evaluations of system 200 established no deposition on the ceiling for run-to-run consistency and long (3000 μm) PM interval.

### Exhaust

The system 200 of FIG. 1 includes a peripheral exhaust port 203 for exhausting gases from the exhaust chamber 201. In combination with the controlled sidewall temperature, the peripheral exhaust port 203 is configured to limit parasitic deposition and avoid exhaust clogging. It will be appreciated that any number of different peripheral exhausts can be used in the system 200.

### Gear Box

As mentioned with respect to the drive mechanism of the system 100, the wafer carrier and the satellites are driven in such a way that each can be independently controlled and rotated. In particular, the wafer carrier (wafer carrier body) is configured to rotate relative to the base at a first rate and the individual satellites mounted within the substrate carrier can rotate relative to the base at a second rate different than the first rate. In one embodiment, the wafer carrier rotates between about 50 RPM and 400 RPM, while the satellites rotate between 20 RPM and 40 RPM. In other words, the wafer carrier rotates at a higher speed than the satellites.

The planetary configuration of the mechanical drive can use a single motor to drive both the satellites and the wafer carrier though reduction gears can be used as described herein. In one embodiment, the wafer carrier and the satellites rotate in the same direction. In another embodiment two motors are used to drive the satellites and the wafer carrier so that the ratio of speeds between the satellites and the wafer carrier can be varied.

FIG. 1 schematically illustrates a pair of gear boxes 205 that are operatively coupled to a pair of satellites for rotating them at a desired speed. The gear boxes 205 sit on the bottom plate 390 of the system 200. These same gear boxes 205 can function to rotate the wafer carrier as well.

It will be appreciated that the gear boxes 205 can have the same or similar constructions as those described herein with respect to the system 100 or they can have other suitable constructions that perform the intended functions.

### Gas Driven Rotation Drive

U.S. Pat. Nos. 6,898,395 and 6,983,620, each of which is hereby expressly incorporated by reference in its entirety, describe and illustrate a gas drive with single satellite gas control that can be modified and implemented in the systems described herein. Gases are fed into the vacuum tight reactor chamber by a multiple gas feed through a hollow shaft ferrofluidic. Each gas channel is controlled by an MFC and supplied to a single satellite. The gas is supplied to a hollow pin to the individual gas drive for each satellite.

Modeling conforms growth rate and uniformity are achievable on 200 mm wafers for a variety of materials. Growth of SiC, GaN, InGaN, GaAs, InAlP, and InGaAsP were evaluated. Deposition on ceiling can be eliminated (SiC) or reduced by >100× (for III-N and As/P) compared to conventional cross flow reactors. Gas usage efficiency and growth rates are comparable or higher than cross flow planetary. Carrier rotational speeds of greater than 100 RPM are adequate. Speeds up to 400 RPM enhance growth rate, improve gas usage efficiency, and expand the process window for uniformity. For carrier rotational speeds up to 100 rpm, a gas drive instead of a gearbox drive can be used

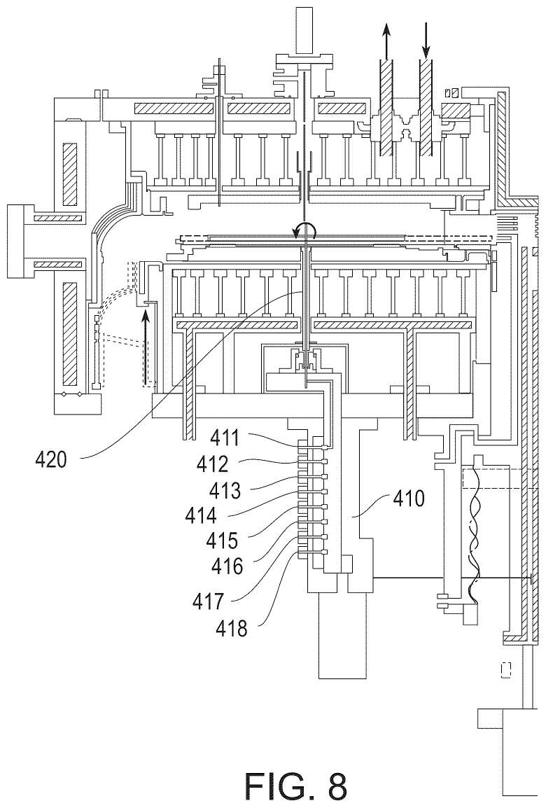

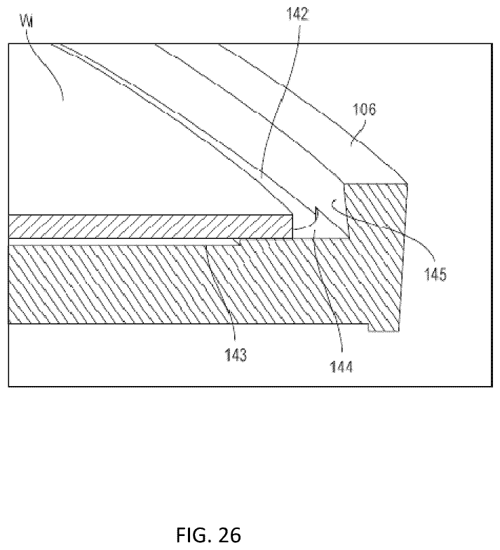

FIG. 8 illustrates a gas drive mechanism incorporated into a system, such as the one shown in FIG. 26, as well as a modified version of system 200 of FIG. 1. Gases are fed into the vacuum tight reactor chamber by 201 a multiple gas feed through a hollow shaft ferrofluidic that is generally indicated at 410. In FIG. 8, there are eight separate satellite gas feeds. For example, there is a first gas feed 411 controlled by MFC (e.g., Ar/H2 or N2/H2); a second gas feed 412 controlled by MFC (e.g., Ar/H2 or N2/H2); a third gas feed 413 controlled by MFC (e.g., Ar/H2 or N2/H2); a fourth gas feed 414 controlled by MFC (e.g., Ar/H2 or N2/H2); a fifth gas feed 415 controlled by MFC (e.g., Ar/H2 or N2/H2); a sixth gas feed 416 controlled by MFC (e.g., Ar/H2 or N2/H2); a seventh gas feed 417 controlled by MFC (e.g., Ar/H2 or N2/H2); and an eighth gas feed 418 controlled by MFC (e.g., Ar/H2 or N2/H2).

Each gas channel 411-418 is controlled by a MFC and supplied to a single satellite. The gas is supplied to a hollow pin 420 to the individual gas drive for each satellite. This system thus utilizes a gas driven rotation drive mechanism to control the rotation of each satellite and the wafer carrier.

This type of architecture of the system 200 provides superior capability compared to conventional systems. The present system 200 allows for operation under isothermal or near-isothermal conditions where the ceiling temperature is comparable to the carrier temperature. This results in improved temperature control, lower temperature sensitivity reduced wafer bow, and enhanced repeatability. The addition of flow and an adjustable flow mixture through the ceiling, active temperature control of the ceiling, and an adjustable carrier rotation speed (e.g., 50 RPM to 400 RPM) provides additional means for process tuning. A broader process window that encompasses a wider range of operating pressure and good uniformity (thickness, composition, and doping) over a wide range of conditions is enabled.

The actively heated and purged ceiling eliminates or reduces deposition on the ceiling, lowers deflectivity, and eliminates chamber drift. By introducing NH3 (carrier gas) through the ceiling, the cracking efficiency of NH3 is increased which may extend the growth window to lower temperatures such as those that are desirable for growing InGaN films with high indium content for red emission. By introducing HCl (etching gas) through the ceiling, the ceiling is kept clean for SiC growth and the growth rate of GaN can be enhanced. In addition, the temperature of non-purged regions above or around the wafer is controlled so that the total accumulation is low enough not to cause memory effects or to generate particles.

One aspect of the present disclosure is the injection of a chlorinated gas, such as HCl (in addition to a carrier gas such as H2, optionally with Ar, through the heated ceiling (at >1650° C. and preferably at 1700°-1750° C.) to suppress deposition on the ceiling. In one embodiment, the wafer temperature is approximately 1650° C. which is the preferred temperature for CVD SiC epitaxy.

In accordance with the present teachings, good uniformity (thickness and nitrogen doping) can be achieved for SiC at 25 μm/hr and 50 μm/hr. Deposition on the ceiling is avoided. For typical cross flow reactors, the upper limit for growth rate with good uniformity is limited to around 25 μm/hr due to parasitic deposition on the ceiling. Advantageously, the construction of the present system 200 overcomes such deficiency and thus, achieves enhanced growth rates with good uniformity.

In addition, good uniformity (thickness and composition) can be achieved for a variety of III-N and As/P materials including under isothermal conditions. Deposition of the ceiling is reduced by >100× compared to the growth rate on the wafer. This shortens the in-situ cleaning time and permits the use of less aggressive cleaning chemistries, such as TBCl, to avoid damage to coatings and chamber components. For typical cross flow reactors, isothermal conditions are not viable due to parasitic deposition on the ceiling. Once again, the present system 200 overcomes this deficiency/limitation.

Based on the foregoing discussion, it will be understood that the system 200 provides the following advantageous features: actively heated ceiling with vertical laminar flow (from the showerhead inlets) for no parasitic deposition, optimal run-to-run repeatability and long PM intervals at high growth rates; multi-zone (e.g., 5 zone) horizontal flow central injector 102 for optimal within-wafer uniformity; controlled sidewall temperature and removable trap (exhaust) to limited parasitic deposition and avoid exhaust clogging; and the planetary drive, together with the temperature-controlled ceiling, provides uniform within-wafer temperature. These combined features are superior to both conventional vertical rotating disk designs and cross flow planetary designs.

### Multiple Zone Resistance Heating for GaN Reactor

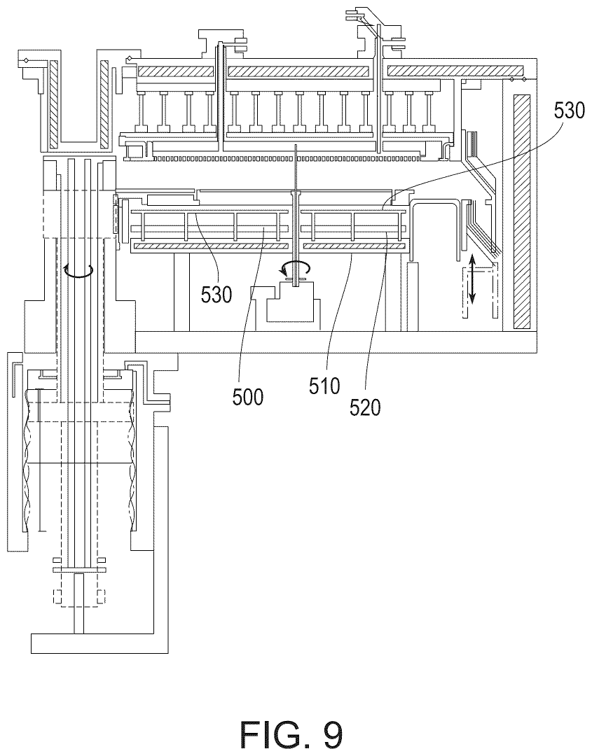

FIG. 9 is a cross-section of a GaN reactor that includes a multiple zone resistance heating arrangement. The system of FIG. 9 incorporates the ceiling heater assembly and the showerhead gas injection in the ceiling as in FIG. 1; however, the susceptor heater is different. More specifically, a multiple zone resistance heater assembly 500 is illustrated for heating the susceptor (carrier and satellites). The assembly 500 generally includes a water-cooled base plate 510 for the heater. Above the base plate 510 there are radiation heat shields 520, with a multi zone resistance heater 530 being disposed above the radiation heat shields 520. The heater 530 can comprises a multi zone resistance heater of a type suitable for the intended application (W or Re).

As with the other embodiments, the multiple zone resistance heater assembly 500 heats the susceptor to the desired temperature (target temperature or range).

### Automated Loading and Unloading of Wafer Carrier

For ease of illustration, in FIGS. 6 and 10-20, a wafer carrier is indicated at 600; a satellite contained within the wafer carrier is indicated at 610; and an end effector is indicated at 620. A wafer 611 is supported by the satellite 610. As is known, an end effector 620 is the device at the end of a robotic arm that is configured to interact with the particular environment in which the robot is present. In the present environment, the end effector is a device that is engineered for handling wafers, for transferring them from one location to another. The wafer carrier 600 has a center opening to accommodate movement of the center gas injector 102.

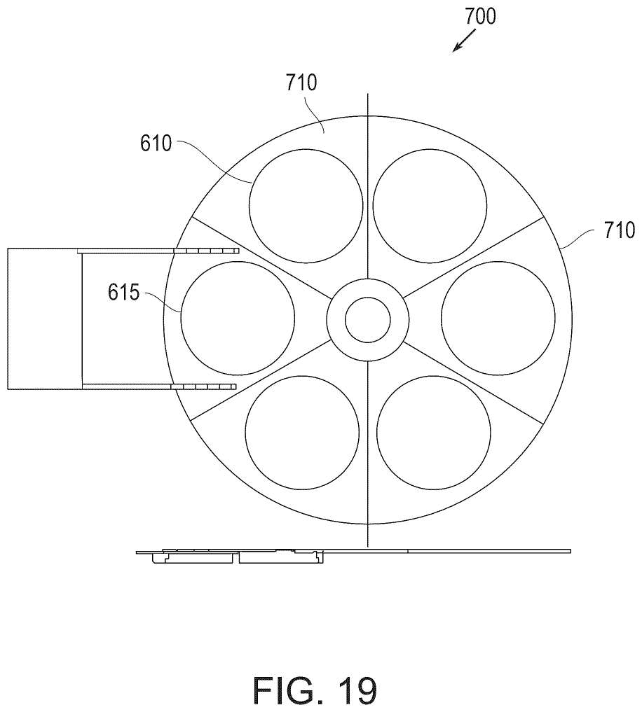

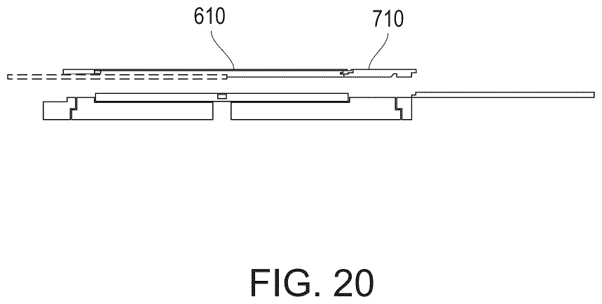

FIG. 6 shows a monolithic wafer carrier 600, while other embodiments illustrated herein (e.g., FIGS. 19 and 20) depict a segmented wafer carrier. When the wafer carrier is a monolithic structure, the automated handling device picks up and moves the entire wafer carrier 600.

### GaN or GaAs Related Materials

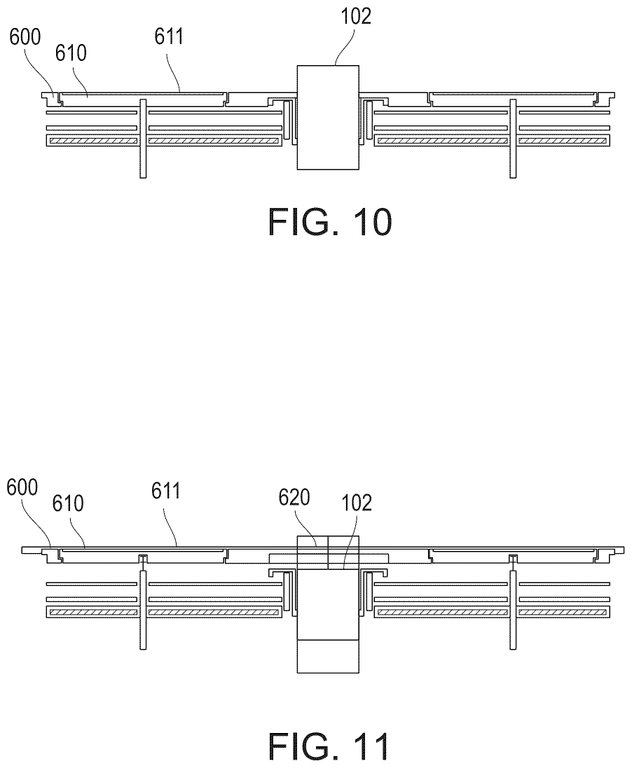

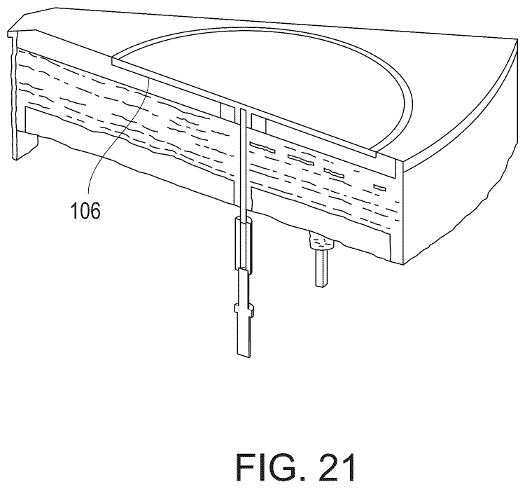

FIGS. 10-14 relate to a reactor setup for GaN or GaAs related materials. Such reactor setup can include a resistance heater (See, FIG. 21).

FIG. 10 illustrates when the reactor is in an in-process status. In the in-process status, the reactor gate is closed, the shutter is closed, the center horizontal gas injector 102 is in the raised position. This raised position allows one or more gas injection zones to be open and above the wafer to allow gas to radially outward from the center gas injector 102.

FIG. 11 shows the reactor in a position for loading and unloading of the carrier 600. In this position, the reactor gate is open to vacuum transfer module chamber; the shutter is down; the center gas injector 102 is moved down the lowered position; and a robot with the end effector 620 is moved into the reactor chamber 201. The end effector 620 moves the carrier 600 including the satellites 610 and the wafers 611 to a raised position to allow for the unloading of the wafer carrier 600. For the initial loading, the end effector 620 moves the carrier 600 into the reaction chamber 201.

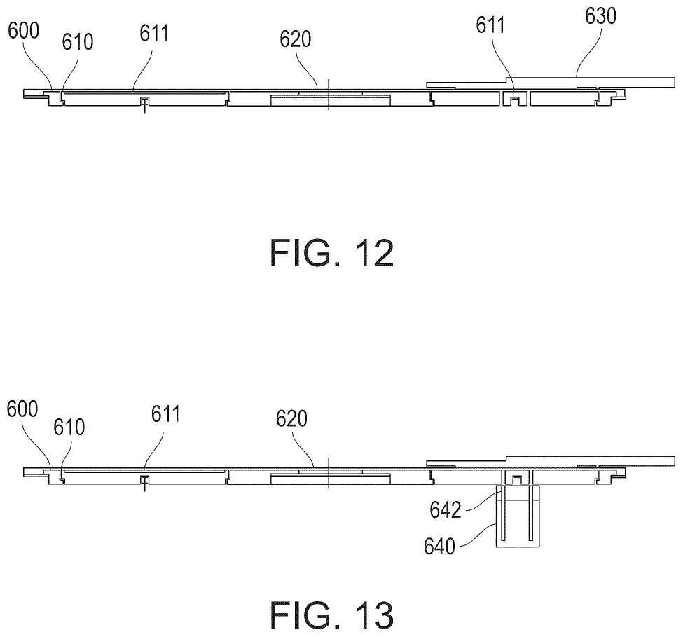

FIGS. 12 and 13 depict the position of the carrier 600 at the wafer loading and unloading station with two different gripping solutions being depicted. The carrier 600 with satellites 610 are transported to the wafer loading and unloading station and are positioned and initialized to a dedicated loading and unloading position.

More specifically, FIG. 12 illustrates a Bernoulli gripper solution. In this arrangement, a Bernoulli gripper 630 is provided. The end effector 620 with Bernoulli gripper 630 at a (second) robot from the wafer module picks up the wafer 611 by switching on gas flow and producing an under pressure for picking the wafer 611 up. The processed wafer 611 is then transported to storage. The process is repeated for all other processed wafers 611 on the carrier 600. After that task is completed, the carrier 600 is replaced with a cleaned carrier 600 and satellites 610. Next, fresh, unprocessed wafers 611 are placed on each satellite 610. The cleaned carrier 600 with fresh, unprocessed wafers 611 on the satellites 610 are transported into the reactor.

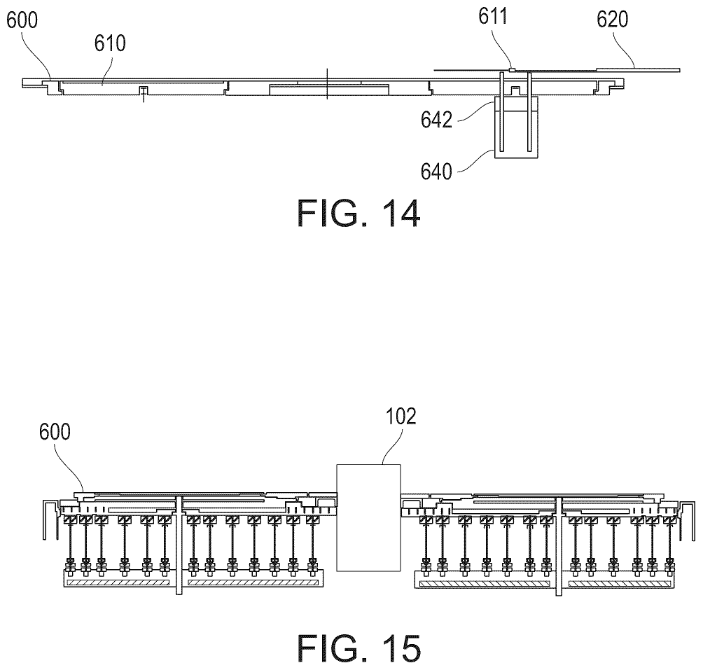

FIGS. 13-14 depict an arrangement in which lift pins are present. FIG. 13 shows a lift pin drive 640 with lift pins 642 in the lowered positions. FIG. 14 shows the lift pins 642 in the raised positions. In the lift pin arrangement of FIGS. 13-14, the wafer 611 is lifted by three lift pins 642 from the satellite 610 to a raised position for catching the wafer 611 by the wafer end effector 620. The satellite 610 include holes that allow for passage of the lift pins 642. After the wafer end effector 620 engages the processed wafer 611, the processed wafer 611 is transported to storage. The process is repeated for all other processed wafers 611 that are contained on the carrier 600. Next, the used carrier 600 is replaced with a cleaned carrier 600 and satellites 610 from a storage facility. The carrier is then positioned and initialized to a dedicated loading and unloading position for each satellite 610. A fresh, unprocessed wafer 611 is placed on one respective satellite 610 by moving up the lift pins 642 and placing the wafer 611 by the wafer end effector 620 on the lift pins 642. The lift pins 642 are then moved down to place the wafer 611 onto the recess of the satellite 610. The cleaned carrier 600 with fresh, unprocessed wafers 611 are then transported into the reactor.

### SiC Related Material

FIGS. 15-18 depict processing steps for a SiC related material using system 200 that includes the RF susceptor heater as well as the ceiling heater.

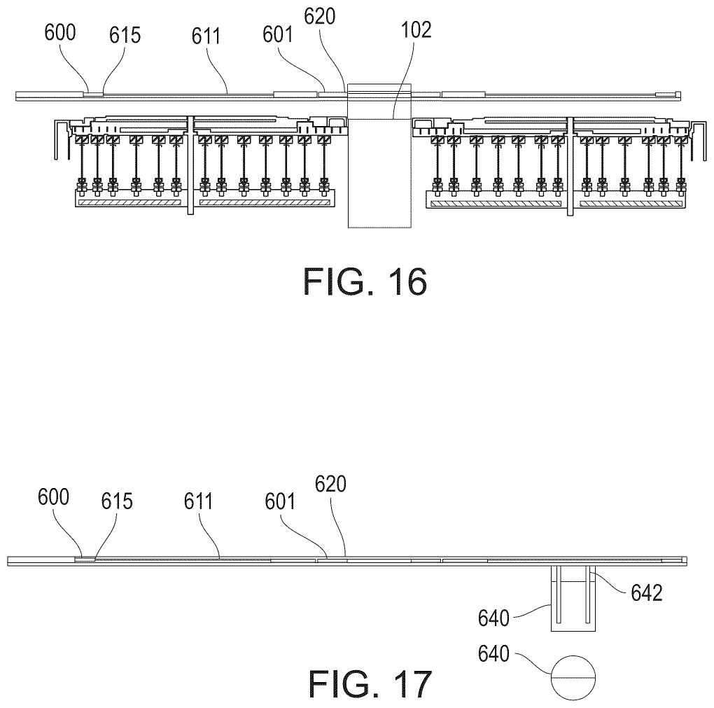

FIG. 15 depicts the in-process reactor position (in process status). In this position, the reactor gate is closed; the shutter is closed; and the center gas injector 102 is in the raised position which allows gas to flow radially outward from the center gas injector 102. FIG. 16 depicts the wafer carrier loading/unloading position. The satellite includes a satellite ring 615 and the carrier 600 includes a carrier inner ring 601. In this position, the reactor gate is open to vacuum transfer module chamber. The center gas injector 102 moves to the lowered position, thereby permitting movement of the end effector. The robot arm with the end effector 620 is moved into the reactor chamber 201. The end effector 620 is operated to move the carrier 600 and satellites 610 to a raised position as shown in FIG. 16.

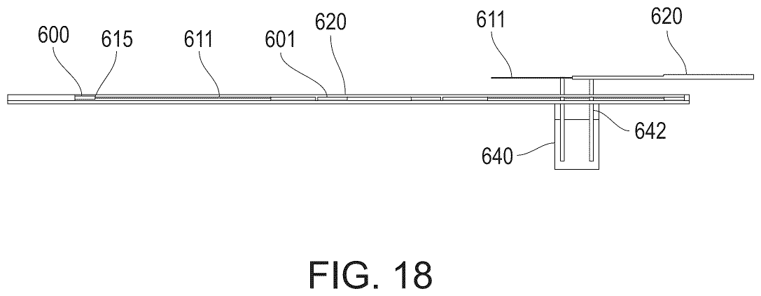

FIGS. 17 and 18 depicts the carrier position at the wafer loading and unloading station. The carrier 600 and satellites 610 are transported by the end effector 620 to the wafer loading and unloading station. The carrier is positioned and initialized to a dedicated loading and unloading position.

FIG. 17 shows the lift pin drive 640 with lift pins 642 in the lowered positions. FIG. 18 shows the lift pins 642 in the raised positions. In the lift pin arrangement of FIGS. 17-18, the wafer 611 is lifted by three lift pins 642 from the satellite 610 to a raised position for catching the wafer 611 by the wafer end effector 620. After the wafer end effector 620 engages the processed wafer 611, the processed wafer 611 is transported to storage. The process is repeated for all other processed wafers 611 that are contained on the carrier 600. Next, the used carrier 600 is replaced with a cleaned carrier 600 and satellites 610 from a storage facility. The carrier is then positioned and initialized to a dedicated loading and unloading position for each satellite 610. A fresh, unprocessed wafer 611 is placed on one respective satellite 610 by moving up the lift pins 642 and placing the wafer 611 by the wafer end effector 620 on the lift pins 642. The lift pins 642 are then moved down to place the wafer 611 onto the recess of the satellite 610. The cleaned carrier 600 with fresh, unprocessed wafers 611 are then transported into the reactor. As previously mentioned, the satellite 610 has features (through holes) that permit movement of the pins 642.

### Segmented Carrier

FIGS. 19-20 depict a separated (segmented) carrier construction. As illustrated, in this embodiment, a carrier 700 is formed of a plurality of discrete sections 710 (“pie shaped sections”) with each section 710 including one satellite 610/satellite ring 615. In this embodiment, the end effector can be in the form of a fork design end effector and the carrier 700 includes complementary grooves that received the forks (arms) of the end effector. FIG. 20 shows the lifting of one discrete section 710 from the main body of the carrier 700 by the fork design end effector. The lifted discrete section 710 includes the one satellite 610/satellite ring 615.

The automated loading/unloading process can include the following steps: moving one carrier section 710 out of the reactor using a robotic device (end effector) and placing the removed section 710 into a wafer loading and unloading station. Once the carrier section is at the wafer loading and unloading station, the wafer 611 is separated (lifted) from the satellite 610/satellite ring 615 and is further processed and/or transported to a different station. After the wafer is removed, the section 710 and the satellite 610/satellite ring 615 are moved to storage.

A cleaned (or new) carrier section 710 (with cleaned satellite 610/satellite ring 615) is then brought into the reaction chamber. For example, the cleaned carrier section 710 (with cleaned satellite 610/satellite ring 615) can be brought to the wafer loading and unloading station. A fresh wafer 611 is loaded onto the section 710 (onto the satellite 610/satellite ring 615) and then the section 710 is then loaded back into an open space in the segmented carrier within the reaction chamber. This process is repeated using an indexed controller that rotates the segmented carrier in indexed increments to the position at which each carrier section 710 is unloaded/loaded. In other words, the carrier is rotated in an indexed manner to position one dirty carrier section 710 at the carrier section load/unload position. Once the dirty carrier section 710 is at this position, it is unloaded and processed as described above and a cleaned carrier section 710 is added back to the carrier. In this way, sequential removal and the replacement of the carrier sections 710 results.

### Clustered System

It will be understood that the systems disclosed herein can be incorporated into a clustered system that comprises two reactors.

### Satellite Construction

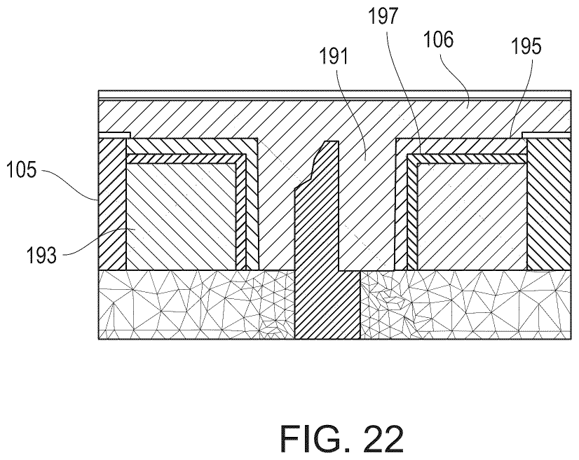

Referring to FIGS. 21 and 22, in some embodiments, a rotatable platform and satellite ring may be driven by a common motor through separate gears to achieve a differential in rotational speed between rotatable platform and satellite ring 116. This results in a differential speed between carrier 105 and satellites 106. This embodiment is preferred when the carrier rotational speed substantially exceeds the satellite rotational speed such as for example when the carrier is rotating at 100-1200 rpm and the satellite is rotating at 20-40 rpm. In this embodiment, substantial centripetal forces act on satellites 106A-F. To counter-act these centripetal forces, satellites 106A-F may be mounted in the carrier via a bushing.

In one embodiment, the carrier rotates at >50 rpm and preferably at >100 rpm, while the satellites 106A-F are rotating slowly (<30 rpm) in order to draw the reactants towards the wafer surface and away from the ceiling (to minimize dilution by the ceiling purge).

Satellite 106 consists of a disc with a hub 191 at the bottom. The hub 191 is positioned within a bushing 193. The bushing 193 is embedded in the base of carrier 105. The interface between the satellite hub 191 and the bushing 193 is designed to have low friction so that the torque required to rotate the satellite under the frictional forces induced by the centripetal forces are minimized. Low friction interfaces can be obtained by coating the mating surfaces with high temperature compatible solid lubricants such as MoS₂ and WS₂. The bushing material and dimensions are chosen to minimize the thermal imprint of the hub 191 on the wafer. The bushing 193 may consist of a combination of materials such as fused silica, graphite, SiC, and molybdenum to achieve the desired properties. For example, as illustrated above, bushing 193 fabricated from quartz may contain two concentric liners 195, 197. The liners 195, 197 can be fabricated from molybdenum and the interfaces between the two liners 195, 197 can be coated with a low friction solid lubricant.

In this configuration, satellite supports 117F contain a flexural element to accommodate a slight radial movement of the satellite due to thermal expansion of the carrier. The interface between the end of satellite supports 117F and the satellites 106A-F is designed to rotatably couple the rotary motion of satellite supports 117F and transmit the torque required to overcome the frictional forces in the bushing.

### Center Cross-Flow Injector 102

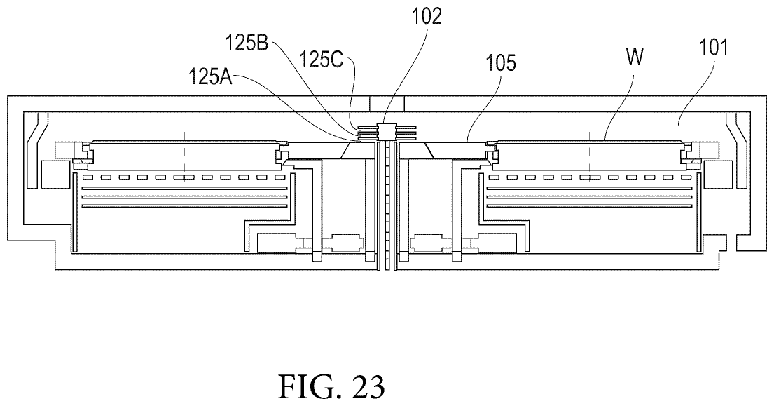

In alternate embodiments, the injector 102 can be centrally positioned within the reaction chamber 201 to affect a substantially horizontal or crossflow of reactant gases over substrates positioned within the reaction chamber. For example, with reference to FIG. 23, a multi-zone injector 102 can be positioned adjacent to the top surface of the wafer carrier 105, so as to have a lateral component with respect to the one or more substrate wafers (W) positioned within the wafer carrier 105. As such, the injector 102 can provide a variable horizontal flow of reactant gas towards exposed growth surfaces of the one or more substrate wafers. As described herein, the multi-zone center injector 102 can be raised and lowered between a load and unloading position, which is the lowered position, in which the wafer carrier can be loaded and unloaded through the load port and a process position, which is the raised position, in which reactant gas flows horizontally out of the injector 102 in a radially outward direction over the wafers that are located on the satellites.

The injector 102 of FIG. 23, as well as FIG. 1, can be considered to provide a horizontal concentric gas inlet with multiple zones for injecting the reactant (process) gases into the reaction chamber 101 with planetary rotation of the satellites to compensate for precursor depletion.

In some embodiments, the centrally located injector 102 can be temperature controlled via the coolant system and can be connected to gas sources for independently introducing one or more of a first reactant gas, second reactant gas, and/or inert gases into the reaction chamber 101. Further, the injector 102 can comprise multiple injection zones stacked vertically. For example, in one embodiment, the injector 102 can include a plurality of inlets 125A-C for injection of the respective first reactant gas, second reactant gas, and inert gases into the reaction chamber as shown in FIG. 23. In one embodiment, the center injector 102 is a five-zone injector that provides good uniformity (thickness and doping) at high growth rates (50 μm/hr). In the raised position, all zones (all of the inlets) are exposed and activated to allow unimpeded flow of the reactant gas from each of the inlets. Conversely, in the lowered position, none of the zones are activated and all of the inlets are closed off.

In some embodiments, the inlets 125A-C can be separated by horizontally oriented baffles configured to enable separation of the process gases into independently regulatable vertical (stacked) zones. In embodiments, the zones can be externally plumbed, so that the zones can operate individually or be ganged together into zones with the appropriate gas mixture fed to each of the zones. For example, for an injector 102 with seven vertically stacked zones with zone one at the bottom and seven at the top, the zones may be assigned as inert gas (zone one), hydride (zone two), alkyl (zone three), hydride (zone four), and inert gas (zone five, zone six, zone seven). In another embodiment, the zones may be assigned as inert gas (zone one), hydride (zone two), alkyl (zone three), hydride (zone four), alkyl (zone five), hydride (zone six), and inert gas (zone seven). Another possible configuration is inert gas (zone one), hydride (zone two), alkyl (zone three, zone four), hydride (zone five, zone six), and inert gas (zone seven). Other embodiments are also contemplated.

In one embodiment, the chlorinated gas (in addition to a carrier gas, such as H2, optionally with Ar) is injected through the topmost zone of the center injector 102 to prevent deposition on the leading edge of the ceiling within the reaction chamber.

The center gas injector 102 has vertically stacked zones with horizontal baffles separating the zones. These baffles can have triangular shapes cross-section to direct the gas radially outward to the wafers that surround the center gas injector 102.

In embodiments, the injector 102 can be centrally located within the reaction chamber 101. Accordingly, reactant gases can be introduced into the reaction chamber via inlets 125A-C to provide a crossflow flow component of reactant gases across an exposed growth surface of one or more substrate wafers positioned within one or more pockets of the wafer carrier 105. In some embodiments, the injector 102 can be mounted on a bellows assembly, so that the injector 102 can be moved vertically up and down relative to the wafer carrier 105 to facilitate case in removal of the wafer carrier 105 between epitaxial growth cycles. In other embodiments, the injector 102 can be positioned in proximity to a periphery of the wafer carrier 105 surrounding carrier 105.

It will also be appreciated that the center injector 102, that affect a substantially horizontal or crossflow of reactant gases over substrates positioned within the reaction chamber 101, is used in combination with the showerhead gas inlet arrangement, discussed herein, that introduces gases into the reaction chamber from the ceiling location.

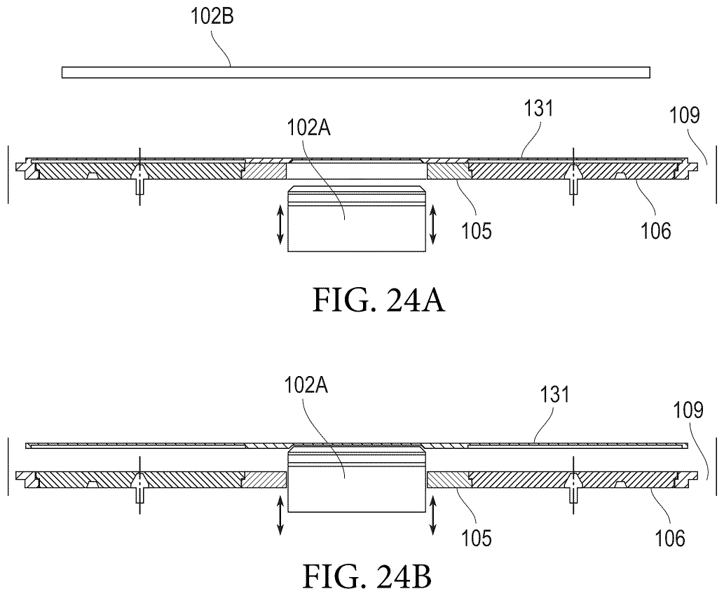

With reference to FIGS. 24A-B, in an alternative embodiment, the cover plate 131 can be raised and lowered with a movable, centrally located gas injector 102A. For example, FIG. 24A depicts the cover plate 131 in the home position, while FIG. 24B depicts the cover plate 131 and injector 102A in the active position. In this embodiment, both the wafer carrier 105 and the individual wafer supporting discs 106 can be configured to rotate slowly, with a flow of reactant gases generally directed across the wafer supporting discs 106 radially outwards from the central injector 102 towards a peripheral exhaust, in a crossflow planetary configuration.

Due to the slow rotational speed of the wafer supporting discs 106, adjacent wafer supporting discs 106 can rotate in either the same direction or an opposite direction. The central injector 102 can be movable below the and upper plane or top surface of the wafer carrier 105 during wafer carrier 105 loading and unloading and moved upwards above the top surface of the wafer carrier 105 once the carrier has been loaded into the chamber 101. Accordingly, the cover plate 131 can be lifted by the injector 102 or by a separate lift mechanism 132, as previously described. Further, in some embodiments, an additional injector 102B can be positioned above the cover plate 131 to produce a flow of inert gases that flow toward the peripheral exhaust 109.

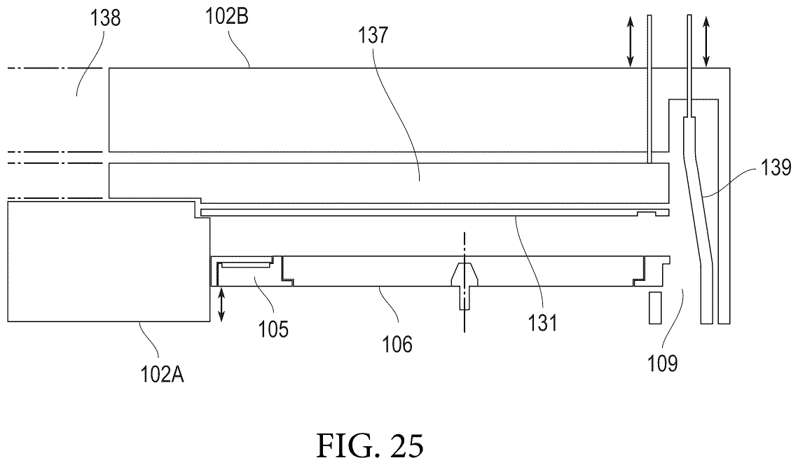

With additional reference to FIG. 25, in some embodiments, the system 100 can include a mechanism for cooling or thermal regulation of the cover plate 131. For example, in one embodiment, the system 100 can include a water-cooled plate 137, positioned above the cover plate 131. In embodiments, the water-cooled plate 137 can be configured to move up and down relative to the cover plate 131 for precise temperature control of the cover plate 131 during operation. Movement of the water-cooled plate 137 can be automated based on data received from in situ metrology. To ensure temperature monitoring of the wafers during operation, in some embodiments, the cover plate 131 and water-cooled plate 137 can include apertures and/or a central viewport for temperature monitoring. In addition to the water-cooled plate 137, in some embodiments, the system can further include a water-cooled chamber top 102B with a water-cooled viewport 138 and inlets for purge gases, a linearly actuated water-cooled shutter 139 configured to serve as an outer surface of the peripheral exhaust 109, and a movable, water-cooled centrally located injector 102A with configurable reactant gas injector zones.

With reference to FIG. 26, wafer satellites 106 can be formed of numerous types of materials, such as graphite, SiC, metal, or ceramic. In some embodiments, it is desirable to form the satellite 106 of a material that can easily accept additional materials 144 in localized areas of different materials or the same material with a different orientation or with modified properties in localized areas. For example, as depicted in FIG. 26, additional materials 144 added to the pocket floor 143 and/or peripheral wall surface 145 of the wafer pocket 142 can be configured to provide additional support for wafer (W) and/or compensate for thermal non-uniformities. In one embodiment, additional materials 144 can be added to or removed from the pocket floor 143 and/or the wall surface 145 by a contouring apparatus.

Additional materials 144 can be positioned at several locations along the peripheral wall or bottom surface of the wafer. Additional materials 144 can be rectangular, stepped, triangular, or sloped in shape. Material 144 can be added, for example, by evaporation, sputtering, plating, CVD, or positioning an additional support therein. Portions of the satellites 106 can be masked so that the additional material 144 is deposited in only certain areas of the satellites 106. As depicted in FIG. 11, the wafer pockets 142 and additional materials 144 can define various gaps or step heights spanning from the pocket floor 143 to the bottom surface of the wafer. In some embodiments, changes in the step height can affect the thermal conductivity of the wafer carrier, to promote a more uniform temperature profile across the top surface of the wafer. In one embodiment, the satellite 106 can include a heat spreader plate configured to provide a controlled gap between the pocket floor 143 in the bottom surface of the wafer, when the wafer is placed within a cavity defined by the heat spreader plate. In embodiments, the heat spreader plate can be constructed of a material with high thermal conductivity, such as CVD SiC or pyrolytic graphite.

In one embodiment, portions of the pocket floor 143 are contoured away to adjust the various step heights spanning from the pocket floor 143 to the bottom surface of the wafer. For example, in one embodiment, a wafer supporting disc 106 is initially produced with a pocket floor 143 having an elevation equal to the highest anticipated point within a finalized pocket floor 143, such that only the removal of material needs to be carried out to produce the final pocket floor 143. Material can be removed from the satellite 106, for example, by machining localized areas in the pocket 142. In such an embodiment, it is desirable to form the satellite 106 of a material that can be easily machined in localized areas to conform to a predefined contour. The satellite 106 can be machined with continuous contours or can be machined in localized areas by pecking with a specialized cutting tool. For example, a small diameter diamond cutting tool can be used. Cutting tools that operate at high speeds, such as cutting tools that use air turbine spindles can provide the relatively high accuracy needed for machining small pixels.

Now turning to FIG. 27 in which another embodiment is illustrated. More specifically, a precision, multi-wafer metal organic chemical vapor deposition system 1000 is provided and includes a reaction chamber 1001 (occasionally referred to herein as a “process chamber” or “reactor”), configured to define a process environment space, in which a gas injector 1010 (alternatively referred to herein as a “gas distribution device”) can be arranged within the environment space. It will be appreciated that the system 1000 and reaction chamber 1001 shares some similarity to the system 200 (FIG. 1) and therefore, like elements are illustrated in the same manner.

In contrast to the center gas injector 102 of FIG. 1, the center gas injector 1010 is stationary (it can be fixed to the center ferrofluidic feedthrough) and does not move in an up and down manner. It will be appreciated that in this embodiment, the wafer carrier comprises a segmented carrier, as described herein. The segmented carrier permits the removal of individual segmented carrier pieces, while the center gas injector 1010 remains fixed and extends vertically through the reaction chamber 1001. More specifically, the carrier in system 1000 comprises carrier 700 that is formed of the plurality of discrete section 710 (FIG. 19).

The individual sections 710 are removed with a device, such as a robotic end effector, that is configured to remove the carrier ring and wafer. The carrier 700 can be rotated in an indexed manner to allow for the individual and successive removal of the carrier sections 710 through a load port or the like. Clearance to remove the carrier can be generated by moving down an exhaust ring or by moving a segment of the exhaust ring.

The center gas injector 1010 is thus configured to affect a substantially horizontal or crossflow of reactant gases over substrates (wafers) positioned within the reaction chamber 1010. The center gas injector 1010 can have the same attributes of the center gas injector 102 in that it can include a plurality of injections zones that are concentric to one another and are arranged in a stacked orientation. Gas is fed from below to the center gas injector 1010.

The system 1000, like system 200, includes the top ceiling plate 300 and the plurality of showerhead holes 311 (FIG. 2) that communicate directly into the reaction chamber 1001. The showerhead holes 311 can be formed in different patterns to allow the uniform distribution of the gases into the reaction chamber 1001.

The reaction chamber 1010 comprises a hot wall reactor and includes a heated sidewall that is water-cooled as a result of the sidewall having an internal chamber in which water is circulated (identical or similar to the one described with reference to FIG. 1). This mechanism allows for controlled sidewall temperature of the reaction chamber 1001. As with the system 200, the ceiling of the reaction chamber 1001 is preferably both heated and includes a showerhead architecture for injecting purge gases into the reaction chamber 1001.

One other difference between the system 1000 and the system 200 is that the gas drive mechanism is different. In particular, instead of having a gas drive mechanism that is located below the satellites, the gas drive mechanism can be incorporated into the center region of the system 1000 and more particularly, the gas drive mechanism can be located along the center axis of the reaction chamber 1001. It will thus be appreciated that, in this embodiment, the gas drive mechanism is located below and/or as part of the center gas injector 1010.

Generally, the gases of the gas drive mechanism are routed through a tub outside of a locking mechanism tube and the center gas injector 1010. Gases are thus fed into the vacuum tight reactor chamber by a multiple gas feed through a hollow shaft ferrofluidic. In FIG. 26, the multiple gas feeds are generally indicated at 1030. For example and according to one embodiment, there can be eight separate satellite gas feeds. For example, there is can a first gas feed controlled by MFC (e.g., Ar/H2 or N2/H2); a second gas feed controlled by MFC (e.g., Ar/H2 or N2/H2); a third gas feed controlled by MFC (e.g., Ar/H2 or N2/H2); a fourth gas feed controlled by MFC (e.g., Ar/H2 or N2/H2); a fifth gas feed controlled by MFC (e.g., Ar/H2 or N2/H2); a sixth gas feed controlled by MFC (e.g., Ar/H2 or N2/H2); a seventh gas feed controlled by MFC (e.g., Ar/H2 or N2/H2); and an eighth gas feed controlled by MFC (e.g., Ar/H2 or N2/H2). Each gas channel is controlled by a MFC and gas is supplied to a single satellite as by a conduit 419 that is fluidly connected to the ferrofluidic feedthrough. This system thus utilizes a gas driven rotation drive mechanism to control the rotation of each satellite and the wafer carrier 700.

The system 1000 thus combines a fixed (stationary) center gas injector 1010 with a segmented wafer carrier 700, along with heated sidewalls and ceiling as described within reference to the system 200.

One advantage of using a center gas feed for the gas drive mechanism is that it simplifies the susceptor (carrier) heater since, unlike some heater designs described herein, the susceptor heater does not need to be split (the split design accommodates the gas drive mechanism located beneath the satellites (as opposed to being located at the center)).

A peripheral exhaust port is illustrated.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

What is claimed is:

1. A multi-wafer metal organic chemical vapor deposition system in which adjacent wafers positioned within the system rotate about their own axes, the system comprising:
a reaction chamber having an exhaust system and a ceiling;
a multi-wafer carrier including a wafer carrier body and a plurality of wafer carrier discs supported within the wafer carrier body;
a ceiling heater assembly disposed along the ceiling above the multi-wafer carrier for heating the ceiling of the reaction chamber;
a ceiling injector positioned along the ceiling over the multi-wafer carrier for injecting gas into the reaction chamber;
a center gas flow port positioned in a center of the multi-wafer carrier; and
a susceptor heater assembly positioned beneath the multi-wafer carrier.

2. The multi-wafer metal organic chemical vapor deposition system of claim 1, wherein the multi-wafer carrier body is configured to rotate.

3. The multi-wafer metal organic chemical vapor deposition system of claim 1, wherein the center gas flow port comprise a movable center gas flow port that comprises a reactant gas inlet port with at least one injection zone.

4. The multi-wafer metal organic chemical vapor deposition system of claim 3, wherein the reactant gas inlet port has a plurality of injection zones.

5. The multi-wafer metal organic chemical vapor deposition system of claim 4, wherein the plurality of injections zones are concentric to one another and are arranged in a stacked orientation.

6. The multi-wafer metal organic chemical vapor deposition system of claim 5, wherein the plurality of injection zones are oriented parallel to one another so as to inject at least one gas into the reaction chamber in a crossflow direction.

7. The multi-wafer metal organic chemical vapor deposition system of claim 1, wherein the ceiling injector includes a top ceiling plate and a lower ceiling plate spaced from the top ceiling plate with an open space formed therein, the lower ceiling plate has showerhead holes formed therethrough for injecting the gas into the reaction chamber.

8. The multi-wafer metal organic chemical vapor deposition system of claim 7, wherein the ceiling heater assembly is disposed above the ceiling injector with a barrier disposed therebetween to prevent the gas from the reaction chamber from flowing into the ceiling heater assembly.

9. The multi-wafer metal organic chemical vapor deposition system of claim 1, wherein the ceiling heater assembly comprises a water-cooled RF coil.

10. The multi-wafer metal organic chemical vapor deposition system of claim 1, wherein the ceiling heater assembly operates at a first temperature that is different than a second temperature at which the susceptor heater assembly operates to permit a temperature gradient between the ceiling and the wafer-carrier body to be reduced to suppress convection by temperature gradient towards the ceiling.

11. The multi-wafer metal organic chemical vapor deposition system of claim 10, wherein the first temperature is greater than the second temperature.

12. The multi-wafer metal organic chemical vapor deposition system of claim 11, wherein the first temperature is between 600° C. and 1200° C. and the second temperature is between 600° C. to 900° C.

13. The multi-wafer metal organic chemical vapor deposition system of claim 1, wherein the susceptor heater assembly comprises a split heater coil defined by an outer coil and an inner coil that is operatively coupled to the outer coil.

14. The multi-wafer metal organic chemical vapor deposition system of claim 1, wherein the susceptor heater assembly comprises a water-cooled RF coil.

15. The multi-wafer metal organic chemical vapor deposition system of claim 1, wherein the wafer carrier body comprises a segmented wafer carrier body with each segment including one wafer carrier disc.

16. The multi-wafer metal organic chemical vapor deposition system of claim 1, wherein the exhaust system comprises a peripheral exhaust located radially outward from each of the multi-wafer carrier, the ceiling heater assembly, and the susceptor heating assembly.

17. The multi-wafer metal organic chemical vapor deposition system of claim 4, wherein the movable center gas flow port moves between a raised position and a lowered position.

18. The multi-wafer metal organic chemical vapor deposition system of claim 17, wherein in the raised position all of the plurality of injection zones are in fluid communication with the reaction chamber and in the lowered position all of the plurality of injection zones are closed off from the reaction chamber.

19. The multi-wafer metal organic chemical vapor deposition system of claim 17, wherein the lowered position comprises a load/unload position of the multi-wafer carrier and the raised position comprises an in process position of the multi-wafer carrier.

20. The multi-wafer metal organic chemical vapor deposition system of claim 1, wherein the gas injected by the ceiling injector comprises a carrier gas and/or an etching gas.

21. The multi-wafer metal organic chemical vapor deposition system of claim 20, wherein the carrier gas comprises H2, N2, Ar, or a combination thereof and the etching gas comprises HCL, Cl2, or TBCl.

22. The multi-wafer metal organic chemical vapor deposition system of claim 1, wherein the center gas flow port is stationary and the wafer carrier body comprises a segmented wafer carrier body with each segment including one wafer carrier disc.

23. The multi-wafer metal organic chemical vapor deposition system of claim 22, further including a gas drive mechanism that includes a plurality of gas feeds located below the center gas flow port and concentric to a center vertical axis of the reaction chamber.

24. A multi-wafer metal organic chemical vapor deposition system in which adjacent wafers positioned within the system rotate about their own axes, the system comprising:
a reaction chamber having an exhaust system and a ceiling;
a multi-wafer carrier including a wafer carrier body and a plurality of wafer carrier discs supported within the wafer carrier body;
a showerhead ceiling injector positioned along the ceiling over the multi-wafer carrier for injecting gas into the reaction chamber, the showerhead ceiling injector including a top ceiling plate and a lower ceiling plate spaced from the top ceiling plate with an open gas distribution space formed therein, the lower ceiling plate having showerhead holes formed therethrough for injecting the gas into the reaction chamber.
a ceiling heater assembly disposed along the ceiling showerhead ceiling injector for heating the ceiling of the reaction chamber;
a center gas injector positioned in a center of the multi-wafer carrier, the center gas injector comprising a reactant gas inlet port with a plurality of injection zones; and
a susceptor heater assembly positioned beneath the multi-wafer carrier;
wherein the ceiling heater assembly operates at a first temperature that is different than a second temperature at which the susceptor heater assembly operates to permit a temperature gradient between the ceiling and the wafer-carrier body to be reduced to suppress convection by temperature gradient towards the ceiling.

25. The multi-wafer metal organic chemical vapor deposition system of claim 24, wherein the first temperature is greater than the second temperature.

26. The multi-wafer metal organic chemical vapor deposition system of claim 25, wherein the first temperature is between 600° ° C. and 1200° ° C. and the second temperature is between 600° C. to 900° C.

27. The multi-wafer metal organic chemical vapor deposition system of claim 24, wherein the center gas injector is movable between a raised position in which the plurality of injection zones are in fluid communication with the reaction chamber and a lowered position in which the plurality of injection zones are closed off from the reaction chamber.

28. The multi-wafer metal organic chemical vapor deposition system of claim 27, wherein the plurality of injection zones are oriented parallel to one another so as to inject at least one gas into the reaction chamber in a crossflow direction.

29. The multi-wafer metal organic chemical vapor deposition system of claim 24, wherein the ceiling heater assembly comprises a water-cooled RF coil.

30. The multi-wafer metal organic chemical vapor deposition system of claim 24, wherein the susceptor heater assembly comprises a split heater coil defined by an outer coil and an inner coil that is operatively coupled to the outer coil.

31. The multi-wafer metal organic chemical vapor deposition system of claim 24, wherein the susceptor heater assembly comprises a water-cooled RF coil.

32. The multi-wafer metal organic chemical vapor deposition system of claim 24, wherein the gas injected by the showerhead ceiling injector comprises a carrier gas and/or an etching gas.

33. The multi-wafer metal organic chemical vapor deposition system of claim 32, wherein the carrier gas comprises H2, N2, Ar, or a combination thereof and the etching gas comprises HCL, Cl2, or TBCl.

34. The multi-wafer metal organic chemical vapor deposition system of claim 32, wherein the gas injected by the showerhead ceiling injector comprises a chlorinated gas through the heated ceiling that is at a temperature of greater than 1650° C. to suppress deposition on the ceiling.

35. The multi-wafer metal organic chemical vapor deposition system of claim 32, wherein the chlorinated gas comprises HCl and the injected gas includes H2 as the carrier gas, optionally with Ar, and the ceiling is heated to between 1700° C. and 1750° C.

36. The multi-wafer metal organic chemical vapor deposition system of claim 24, wherein the plurality of injection zones includes a topmost injection zone and a chlorinated gas is injected through the topmost zone of the center injector to prevent deposition on a leading edge of the ceiling.

37. A multi-wafer metal organic chemical vapor deposition system in which adjacent wafers positioned within the system rotate about their own axes, the system comprising:
a reaction chamber having an exhaust system and a ceiling;
a multi-wafer carrier including a wafer carrier body and a plurality of wafer carrier discs supported within the wafer carrier body, wherein the wafer carrier body comprises a segmented wafer carrier body with each segment including one wafer carrier disc;
a ceiling heater assembly disposed along the ceiling above the multi-wafer carrier for heating the ceiling of the reaction chamber;
a ceiling injector positioned along the ceiling over the multi-wafer carrier for injecting gas into the reaction chamber;
a stationary center gas flow port positioned in a center of the multi-wafer carrier,
a susceptor heater assembly positioned beneath the multi-wafer carrier, and
a gas drive mechanism that includes a plurality of gas feeds located below the center gas flow port and concentric to a center vertical axis of the reaction chamber and radially inward from the wafer carrier discs.
